(19) United States
(12) Patent Application Publication
(10) Pub. No.: US 2025/0202345 A1
(43) Pub. Date: Jun. 19, 2025

(54) INVERTER ARRANGEMENT FOR MONITORING THE TEMPERATURE OF POWER SEMICONDUCTORS

(71) Applicant: ZF Friedrichshafen AG, Friedrichshafen (DE)

(72) Inventors: Timo Losch, Poppenricht (DE); Sebastian Haller, Burglengenfeld (DE); Thomas Wittig, Gesees (DE); Hermann Thurn, Eckersdorf (DE); Christoph Schikora, Regensburg (DE)

(73) Assignee: ZF Friedrichshafen AG, Friedrichshafen (DE)

(21) Appl. No.: 18/981,015

(22) Filed: Dec. 13, 2024

(30) Foreign Application Priority Data
Dec. 14, 2023 (DE) 10 2023 212 656.7

(51) Int. Cl. H02M 1/32; B60L 50/51; B60L 50/60

(52) U.S. Cl. CPC H02M 1/327; B60L 50/51; B60L 50/60; B60L 2200/18; B60L 2200/36; B60L 2210/40; B60Y 2400/302

(57) ABSTRACT

An inverter assembly contains at least one semiconductor package with external electrical connections, and at least one external connecting pin for a signal or control terminal, a printed circuit board placed above and spaced apart from the semiconductor package, wherein the at least one connecting pin passes through a hole in the printed circuit board and is attached thereto, and a temperature sensor placed near the at least one connecting pin on the printed circuit board, such that it can measure the temperature of a power semiconductor in the semiconductor package transferred to the connecting pin.

### CROSS-REFERENCE TO RELATED APPLICATION

This application claims priority to German Patent Application No. 10 2023 212 656.7, filed on Dec. 14, 2023, the entirety of which is hereby fully incorporated by reference herein.

### TECHNICAL FIELD

The present disclosure relates to the field of electric mobility, in particular monitoring the temperature of power semiconductors in a semiconductor package incorporated in an inverter for a power electronics module for operating an electric drive.

### BACKGROUND

Electronic modules such as power electronics modules have been used to an increasing extent in motor vehicles over the last decades. This is because of the need to reduce fuel consumption and improve vehicle performance, and because of the advances in semiconductor technology. The main parts of such an electronics module, also referred to as power electronics, are an electronic control unit (ECU) connected to or part of the vehicle control units, which receives control signals and/or information based on the performance of the vehicle, or signals from other control units, and a DC/AC inverter, which supplies a multiphase alternating current (AC) to electric machines such as motors or generators. This involves converting direct current from a DC power source such as a rechargeable battery into multiphase alternating current. The inverters contain numerous electronic components for this, with which bridge circuits (half bridges) such as semiconductor switches, also referred to as power semiconductors, are formed.

The power semiconductors are temperature-sensitive and must therefore be kept cool with a cooling system. This requires monitoring the temperature of at least some of the power semiconductors in order to be able to take necessary measures if they become overheated, to prevent damage to the overall inverter system. There are numerous ways of monitoring the temperature of power semiconductors. Temperature monitoring can be integrated directly in power semiconductor packages, e.g. in form of temperature sensors or sensor diodes. The temperature of the semiconductor package can also be measured directly, i.e. on the housing of the power semiconductor. This can take place with or without direct contact to the housing.

### SUMMARY

Because many of these approaches are not only expensive, but also difficult, an object of the present disclosure is to improve temperature measurement of power semiconductors in a semiconductor package.

This problem is solved by the features disclosed herein. Advantageous designs are also the subject matter of the present disclosure.

An inverter assembly is proposed that contains at least one semiconductor package that has external power connections and at least one external connecting pin for a signal or control terminal, as well as a printed circuit board above and spaced apart from the semiconductor package, through a hole in which the at least connecting pin passes and is fastened thereto, and a temperature sensor placed on the printed circuit board near the connecting pin, such that it can measure the temperature transferred to the connecting pin from a power semiconductor in the semiconductor package.

This temperature sensor can be placed on the upper surface of the printed circuit board, facing away from the semiconductor package, or on the lower surface of the printed circuit board, facing toward the semiconductor package.

The temperature sensor can be placed as close as possible to the connecting pin, without physically touching it.

The temperature sensor can be placed at a predefined distance to the connecting pin, with at least one conductor path on the printed circuit board from the temperature sensor to the connecting pin through which heat is transferred.

The temperature sensor can be a surface-mounted device (SMD).

The temperature sensor can be connected to an evaluation unit in the inverter that processes the temperatures measured by the temperature sensor in order to detect overheating.

In one design, a plastic component, or plastic hybrid component, that has a hole in the middle, is placed on the surface of the semiconductor package facing the printed circuit board, and the temperature sensor is placed on the printed circuit board above this hole.

Power electronics for operating a three-phase electric motor in a vehicle are also obtained with the present disclosure, which contain both the inverter assembly and at least one electronic control unit connected to the electric motor and the inverter.

An electric drive for a vehicle is also obtained, which contains a three-phase electric motor and a battery, as well as the power electronics connected thereto.

Other features and advantages of the present disclosure can be derived from the following descriptions of exemplary embodiments in reference to the drawings illustrating details of the present disclosure, and from the claims. The individual features can be obtained in and of themselves or in arbitrary combinations, forming different variations of the present disclosure.

Preferred embodiments shall be explained in greater detail below in reference to the drawings.

### BRIEF DESCRIPTION OF THE DRAWINGS

FIG. 1 shows an inverter structure that contains a temperature sensor placed in accordance with one embodiment of the present disclosure.

FIG. 2 shows an inverter structure that contains a temperature sensor placed in accordance with an alternative embodiment of the present disclosure.

FIG. 3 shows an inverter structure that contains a temperature sensor placed in accordance with an alternative embodiment of the present disclosure.

### DETAILED DESCRIPTION

Identical elements and functions have the same reference symbols in the drawings.

One or more housed power semiconductors (chips) are referred to as a semiconductor package 4, which form high side or low side switches with (stripped) electrical or signal terminals. A half bridge module is also understood to be a semiconductor package 4, which already contains high side and low side switches in a housing.

Current semiconductor packages 4 also contain at least one external signal or control terminal, in addition to the electrical connections, which can be a gate or a Kelvin-source terminal. These signal or control terminals are secured in place near the power semiconductors (chips) inside the semiconductor package 4. The pins 40, 41 thereof come in contact with a printed circuit board 2 above the semiconductor package 4, normally via through-hole technology (THT), in that the pins pass through holes in the printed circuit board, and are secured in place, e.g. through soldering, on the top thereof.

As stated above, it is important to monitor the temperature of a semiconductor package 4 to be able take measures in case of overheating, in order to protect the semiconductor package 4, specifically the power semiconductors (chips) therein. Temperature sensors placed near the semiconductor package 4 are used for this. Because some of the methods for measuring temperatures are very complicated, a simple concept is proposed below that is both inexpensive and can be easily implemented, in particular with an inexpensive temperature sensor.

It is proposed to use one of the connecting pins 40 or 41 for a signal or control terminal in the semiconductor package 4 to measure the temperature of the power semiconductor (chip) therein. Because the connecting pin 40 or 41 for the signal or control terminals are near the power semiconductor (chips) and made of a thermally conductive material such as copper, they absorb the heat thereof and transport it to the printed circuit board 2. One of these pins 40 or 41 can therefore be used for the proposed temperature measurement. In accordance with various embodiments, a temperature sensor 3 is also as close as possible to the connecting pin 40 or 41 without touching it on the printed circuit board 2, i.e. at a distance D (see FIG. 2) thereto.

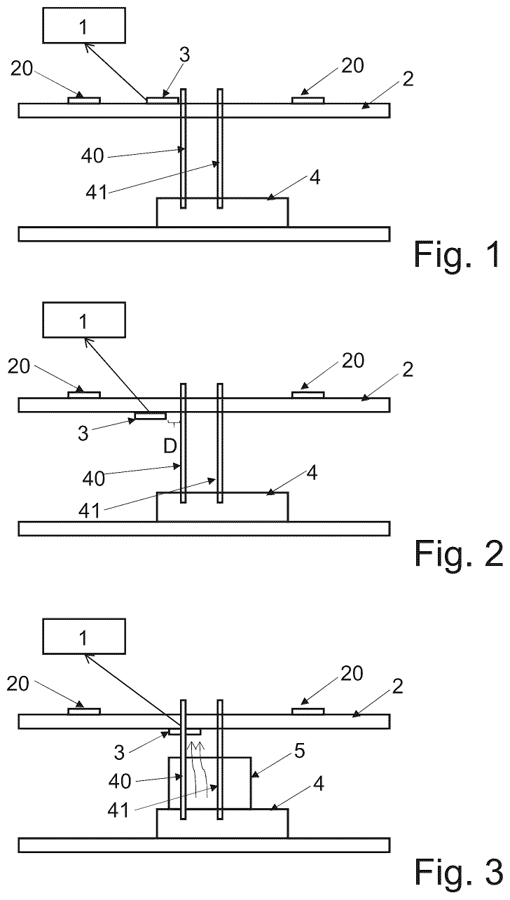

The temperature sensor 3 can be placed on the upper surface of the printed circuit board 2, as shown in FIG. 1, or on the lower surface, facing the semiconductor package 4, as shown in FIG. 2. It is preferably a surface-mounted device (SMD), because it can be attached to the printed circuit board 2 with other components 20 in the surface-mount technology (SMT) process used for populating it.

The temperature sensor 3 is also connected to an evaluation unit 1, e.g. via a conductor path integrated in the printed circuit board 2. This evaluation unit 1 be part of an (external) electronic control unit for the power electronics in the vehicle, or it can be a separate (external, or on the printed circuit board 2) unit connected thereto. It processes the data from the temperature sensor 3 to determine whether the detected temperature is within the acceptable range. If this is not the case, i.e. it exceeds a predefined temperature, the evaluation unit 1 initiates appropriate measures for protecting the power semiconductor (chips), e.g. the inverter is shut off. It is connected to the electronic control unit for the power electronics for this.

There can also be one or more conductor paths between the pin (pin 40 in this embodiment) for the signal or control terminals and the temperature sensor 3 to span the distance D if necessary. These conductor paths are only used for heat transfer, and are therefore not connected electrically to other components 20. In FIG. 1, the temperature sensor 3 is as close as possible to the pin 40, but is further away in FIG. 2, at the distance D. In this case, the heat transfer can be supported by the conductor path.

In one embodiment, the temperature measurement can be improved with an element, preferably a plastic component 5 and/or plastic hybrid component 5, placed on top of the semiconductor package 4, which has a hole facing the top of the semiconductor package 4, as shown in FIG. 3. The element can already be on the semiconductor package 4, or it can be placed there specifically for the temperature measurement. The hole forms a type of chimney, which conducts the heat radiated from the semiconductor package 4 toward the bottom of the printed circuit board 2, and thus to the temperature sensor 3. In this embodiment, the temperature sensor 3 is ideally placed on the bottom of the printed circuit board.

The proposed inverter assembly is part of the power electronics used in an electric drive for a vehicle, which contains a three-phase electric motor and a battery. The power electronics contains an inverter with numerous phases, and is connected to the electric motor and the battery in order to convert direct current from the battery into alternating current that can be used to operate the electric motor. There is an electronic control unit (ECU) for the inverter, which is part of the power electronics. The ECU is connected to the electric motor and the inverter. This electric motor forms an electric axle drive.

A vehicle, e.g. a passenger automobile or utility vehicle, preferably contains at least one such electric drive. The vehicle is specifically a utility vehicle such as a truck or bus, or a passenger automobile. The power electronics module (i.e. the power electronics) contains a DC/AC inverter with the structure described above. It can also be an AC/DC rectifier, a DC/DC converter, a transformer, and/or another electric converter, or it can contain or be a part of such a converter. In particular, the power electronics module is used to power an electric machine, e.g. an electric motor and/or generator.

### List of Reference Symbols

1 control unit (ECU)
2 printed circuit board
20 components populating 2
3 temperature sensor
4 semiconductor package
40, 41 connecting pins for signal or control terminals
5 component
D distance between 3 and 40/41

1. An inverter assembly, comprising:
at least one semiconductor package with external electrical connections, and at least one external connecting pin for a signal or control terminal;
a printed circuit board placed above and spaced apart from the semiconductor package, wherein the at least one connecting pin passes through a hole in the printed circuit board and is attached thereto; and
a temperature sensor placed near the at least one connecting pin on the printed circuit board, such that the temperature sensor can measure a temperature of a power semiconductor in the semiconductor package transferred to the connecting pin.

2. The inverter assembly according to claim 1,
wherein the temperature sensor is on an upper surface of the printed circuit board facing away from the semiconductor package, or on a lower surface of the printed circuit board facing toward the semiconductor package.

3. The inverter assembly according to claim 2,
wherein the temperature sensor is as close to the connecting pin as possible without touching the connecting pin.

4. The inverter assembly according to claim 2,
wherein the temperature sensor is at a predefined distance to the connecting pin, and
wherein there is at least one conductor path on the printed circuit board, which leads from the temperature sensor to the connecting pin and transfers heat.

5. The inverter assembly according to claim 2,
wherein the temperature sensor is a surface mount device (SMD).

6. The inverter assembly according to claim 2,
wherein the temperature sensor is connected to an evaluation unit in the inverter assembly,
wherein the evaluation unit is configured to process temperatures measured by the temperature sensor such that the evaluation unit can detect when a predefined temperature has been exceeded.

7. The inverter assembly according to claim 2,
wherein a plastic component or plastic hybrid component that has a central hole is placed on a surface of the semiconductor package facing the printed circuit board, and
wherein the temperature sensor is placed on the printed circuit board above the hole.

8. The inverter assembly according to claim 1,
wherein the temperature sensor is as close to the connecting pin as possible without touching the connecting pin.

9. The inverter assembly according to claim 1,
wherein the temperature sensor is at a predefined distance to the connecting pin, and
wherein there is at least one conductor path on the printed circuit board, which leads from the temperature sensor to the connecting pin and transfers heat.

10. The inverter assembly according to claim 1,
wherein the temperature sensor is a surface mount device (SMD).

11. The inverter assembly according to claim 1,
wherein the temperature sensor is connected to an evaluation unit in the inverter assembly,
wherein the evaluation unit is configured to process temperatures measured by the temperature sensor such that the evaluation unit can detect when a predefined temperature has been exceeded.

12. The inverter assembly according to claim 1,
wherein a plastic component or plastic hybrid component that has a central hole is placed on a surface of the semiconductor package facing the printed circuit board, and
wherein the temperature sensor is placed on the printed circuit board above the hole.

13. Power electronics for operating a three-phase electric motor in a vehicle, wherein the power electronics comprises:
the inverter assembly according to claim 1; and
at least one electronic control unit connected to the electric motor and the inverter assembly.

14. An electric drive for a vehicle, comprising;
a three-phase electric motor;
a battery; and
the power electronics according to claim 13, wherein the power electronics are connected to both the three-phase electric motor and the battery.
